(19) United States
(12) Patent Application Publication
(10) Pub. No.: US 2026/0200725 A1
(43) Pub. Date: Jul. 16, 2026

(54) MICROSENSOR WITH A PROTECTIVE MASS

(71) Applicant: Robert Bosch GmbH, Stuttgart (DE)

(72) Inventors: Bernhard Maier, Horb (DE); Arne Dannenberg, Metzingen (DE); Volkmar Senz, Metzingen (DE); Martin Kittel, Stuttgart (DE)

(21) Appl. No.: 19/437,403

(22) Filed: Dec. 31, 2025

(30) Foreign Application Priority Data
Jan. 16, 2025 (DE) 10 2025 101 442.6

(51) Int. Cl. B81B 7/00

(52) U.S. Cl. CPC B81B 7/0058; B81B 2201/02; B81B 2203/0127; B81B 2203/0163

(57) ABSTRACT

A microsensor for detecting a measured variable. The microsensor includes: a substrate constructed from a layer structure in a normal direction; at least one sensor element detecting a measured variable; a carrier element that is largely set free from the substrate at least by a lateral clearance region and that includes the sensor element; wherein, in the normal direction above the sensor element and at least in the lateral clearance region, a gel-like protective mass is introduced, which is expandable into a further lower clearance region that is in each case unfilled by the protective mass and is arranged below the carrier element in the normal direction and/or into a further lateral clearance region that is introduced laterally offset relative to the lateral clearance region.

### CROSS REFERENCE

The present application claims the benefit under 35 U.S.C. § 119 of Germany Patent Application No. 10 2025 101 442.6 filed on January 16, 2025, which is expressly incorporated herein by reference in its entirety.

### FIELD

The present invention relates to a microsensor.

### BACKGROUND INFORMATION

Germany Patent Application No. DE 10 2022 205 516 A1 describes a micromechanical component having a membrane that is arranged in a carrier element suspended via a beam and set free by a clearance region.

### SUMMARY

According to the present invention, a microsensor for detecting a measured variable is provided. According to an example embodiment of the present invention, the microsensor includes a substrate constructed from a layer structure in a normal direction; at least one sensor element detecting a measured variable; a carrier element that is largely set free from the substrate at least by a lateral clearance region and that comprises the sensor element; wherein, in the normal direction above the sensor element and at least in the lateral clearance region, a gel-like protective mass is introduced, which is expandable into a further lower clearance region that is in each case unfilled by the protective mass and is arranged below the carrier element in the normal direction and/or into a further lateral clearance region that is introduced laterally offset relative to the lateral clearance region.

As a result, the microsensor can be better protected against environmental influences and the sensor element can be better decoupled from material stresses that act in particular due to the protective mass. The microsensor can be formed cost-effectively and in a space-saving manner.

A height refers to an extent along the normal direction. A length and a width in each case refer to lateral directions perpendicular to the normal direction. A lateral direction is understood to be a direction lying in the plane of which the normal runs parallel to the normal direction. The length can be the extent in one lateral direction and the width can be the extent in a lateral direction perpendicular thereto.

The microsensor can be a microelectromechanical sensor. The microsensor can be a pressure sensor, a microphone, an acceleration sensor and/or a gas sensor. The measured variable can be a fluid pressure, an acceleration and/or a gas property or mass.

According to an example embodiment of the present invention, the sensor element can comprise a membrane that can be deflected into a cavity, in particular in the normal direction. The microsensor can measure the measured variable according to the deflection of the membrane. The sensor element can face an environment of the microsensor.

The carrier element and/or the substrate can be constructed from a plurality of layers, for example from at least one silicon layer, a silicon oxide layer and/or a silicon nitride layer. The carrier element can be suspended on the substrate in a spring-like manner. The carrier element can be largely set free by the lateral clearance region in that a main part of the laterally circumferential outer shell of the carrier element is set free.

The sensor element and/or the carrier element can be formed to be rectangular, in particular square, round or elliptical. The width can be a dimension in a longitudinal or radial direction, and the length can be a dimension in a transverse or circumferential direction.

According to an example embodiment of the present invention, the microsensor can comprise a housing that laterally surrounds the carrier element. The housing can be arranged on the substrate. The housing can be constructed from metal and/or plastics.

The gel-like protective mass can be a protective gel, in particular a silicone-containing gel. The gel-like protective mass can also be a liquid introduced to protect at least the sensor element from the environment, at least with a higher viscosity than water. The protective mass can be arranged directly on the sensor element. The protective mass can be arranged laterally beyond the sensor element. The protective mass can extend laterally above the sensor element as far as the housing.

According to an example embodiment of the present invention, the further lateral clearance region can overlap a height of the carrier element, at least partially, and in particular completely. A height of the further lateral clearance region can be greater than, equal to, or less than a height of the carrier element. The further lateral clearance region can extend along a length and/or width of the carrier element. The further lateral clearance region can extend over a main part of the length and/or width of the carrier element. The further lateral clearance region can extend circumferentially largely around the carrier element. The further lateral clearance region can, in the normal direction, adjoin the substrate at the bottom. A height of the lateral clearance region can be less than, equal to, or greater than a height of the further lateral clearance region. The further lateral clearance region can be open or closed toward an environment of the microsensor. The further lateral clearance region can comprise at least one opening toward the environment of the microsensor.

The lower and/or lateral clearance region can contain a gas, in particular air. A fluid pressure in the lower and/or lateral clearance region can be the same as or different from an ambient pressure in the environment of the microsensor.

In a preferred embodiment of the present invention, it is advantageous if the carrier element is still largely set free in the normal direction below the carrier element by a lower clearance region and the protective mass is also introduced into the lower clearance region. The carrier element can be largely set free in that a main part of the lateral dimensions of the carrier element is set free.

According to an example embodiment of the present invention, the carrier element can be fully set free laterally by the lateral clearance region and downward in the normal direction by the lower clearance region, except for one or more mutually spaced connection regions that connect the carrier element to the substrate. The particular connection region can make a spring-like suspension, for example a beam-like suspension, of the carrier element on the substrate possible.

The further lower clearance region can laterally overlap the carrier element, at least partially, in particular completely. The further lower clearance region can laterally have a width and/or length that is greater than a lateral width and/or length of the carrier element. The further lower clearance region can extend along a length and/or width of the carrier element. The further lower clearance region can extend over a main part of the width and/or length of the carrier element. The further lower clearance region can laterally span at least the main part of the surface of the carrier element. The further lower clearance region can, in the normal direction, in particular adjoin the substrate at the bottom. A height of the lower clearance region can be less than, equal to, or greater than a height of the further lower clearance region. The further lower clearance region can comprise at least one opening toward the environment of the microsensor.

In an advantageous embodiment of the present invention, the further lower clearance region is arranged in the normal direction below the lower clearance region. The further lower clearance region can be arranged in the normal direction between the lower clearance region and the substrate. The further lower clearance region can be open toward an environment of the microsensor, particularly completely and laterally.

In a preferred embodiment of the present invention, the further lower clearance region is arranged in the normal direction between the sensor element and the lower clearance region. The further lower clearance region can laterally adjoin the lateral clearance region and/or the further lateral clearance region. The further lower clearance region can be assigned to the carrier element. The further lower clearance region can be formed in, at, or on the carrier element.

In a specific example embodiment of the present invention, it is advantageous if the further lateral clearance region is arranged laterally between the lateral clearance region and the substrate. The further lateral clearance region can be completely closed or can comprise at least one opening toward the environment of the microsensor.

In a specific example embodiment of the present invention, it is advantageous if the further lateral clearance region is arranged laterally between the carrier element and the lateral clearance region. The further lateral clearance region can adjoin the lower clearance region and/or the further lower clearance region in the normal direction. The further lateral clearance region can be assigned to the carrier element. The further lateral clearance region can be formed in, at, or on the carrier element.

In a preferred embodiment of the present invention, it is advantageous if the protective mass directly adjoins the further lower and/or further lateral clearance region. The further lower clearance region can be enclosed by the substrate, in the normal direction below, at least partially, in particular completely. The further lateral clearance region can be laterally enclosed by the substrate, at least partially, in particular completely.

In a specific example embodiment of the present invention, it is advantageous if a membrane structure is arranged between the protective mass and the further lower and/or further lateral clearance region, which membrane structure separates the protective mass from the further lower and/or further lateral clearance region, but is deflectable to allow the protective mass to expand into the further lower and/or further lateral clearance region. A length and/or width of the membrane structure can be greater than, equal to, or less than a width and/or length of the further lateral and/or further lower clearance region. A height of the membrane structure can be greater than, equal to, or less than a height of the further lateral and/or further lower clearance region.

The membrane structure can comprise openings that are impermeable to the protective mass. The membrane structure can be a grid structure.

The deflection of the membrane structure can be detectable, for example in order to ascertain an expansion of the protective mass, from which in turn conclusions, in particular regarding a temperature, are possible.

In a specific example embodiment of the present invention, it is advantageous if the membrane structure is arranged laterally between the protective mass and the further lateral clearance region. The membrane structure can extend mainly in the normal direction. The membrane structure can be laterally deflectable.

A preferred embodiment of the present invention is advantageous in which the membrane structure is arranged, in the normal direction, between the protective mass and the further lower clearance region. The membrane structure can extend mainly laterally. The membrane structure can be deflectable in the normal direction.

Further advantages and advantageous embodiments of the present invention can be found in the description of the figures and in the figures.

### BRIEF DESCRIPTION OF THE DRAWINGS

### The present invention is described in detail below with reference to the figures

FIG. 1 to 14 in each case show a cross-section of a microsensor in a specific example embodiment of the present invention.

### DETAILED DESCRIPTION OF EXAMPLE EMBODIMENTS

FIG. 1 shows a microsensor 10 for detecting a measured variable, comprising a substrate 14 constructed from a layer structure in a normal direction 12, a sensor element 18 detecting a measured variable and facing an environment 16 of the microsensor 10, and a carrier element 22 that is largely set free from the substrate 14 at least by a lateral clearance region 20 and that comprises the sensor element 18. The carrier element 22 is, for example, fully set free laterally and in the normal direction except for a connection region 23. The connection region 23 can make a spring-like suspension, for example a beam-like suspension, of the carrier element 22 on the substrate 14 possible.

A housing 24 laterally surrounding the carrier element 22 is arranged on the substrate 14. The housing 24 can be constructed from metal and/or plastics.

The carrier element 22 is further largely set free in the normal direction 12 below the carrier element 22 by a lower clearance region 26, which means that the lower clearance region 26 extends at least over the main part of the lateral surface of the carrier element 22, here in particular over the entire width 34 of the carrier element 22 and beyond, and in particular also over the entire length of the carrier element 22, in particular beyond.

In the normal direction 12 above the sensor element 18 and in the lower clearance region 26 and the lateral clearance region 20, a gel-like protective mass 28 is introduced, which extends laterally in the normal direction 12 above the sensor element 18 as far as the housing 24.

Furthermore, in the normal direction 12 below the carrier element 22, a further lower clearance region 30 that is unfilled by the protective mass 28 is arranged. The further lower clearance region 30 is arranged in the normal direction 12 between the lower clearance region 26 and the substrate 14 and completely overlaps the carrier element 22 laterally. The further lower clearance region 30 has a width 32 that is greater than a width 34 of the carrier element 22. The further lower clearance region 30 can also have a length that is greater than a length of the carrier element 22. The further lower clearance region 30 is arranged, in the normal direction 12 at the bottom, in particular adjoining the substrate 14, and a height 36 of the further lower clearance region 30 is here in particular less than a height 38 of the lower clearance region 26.

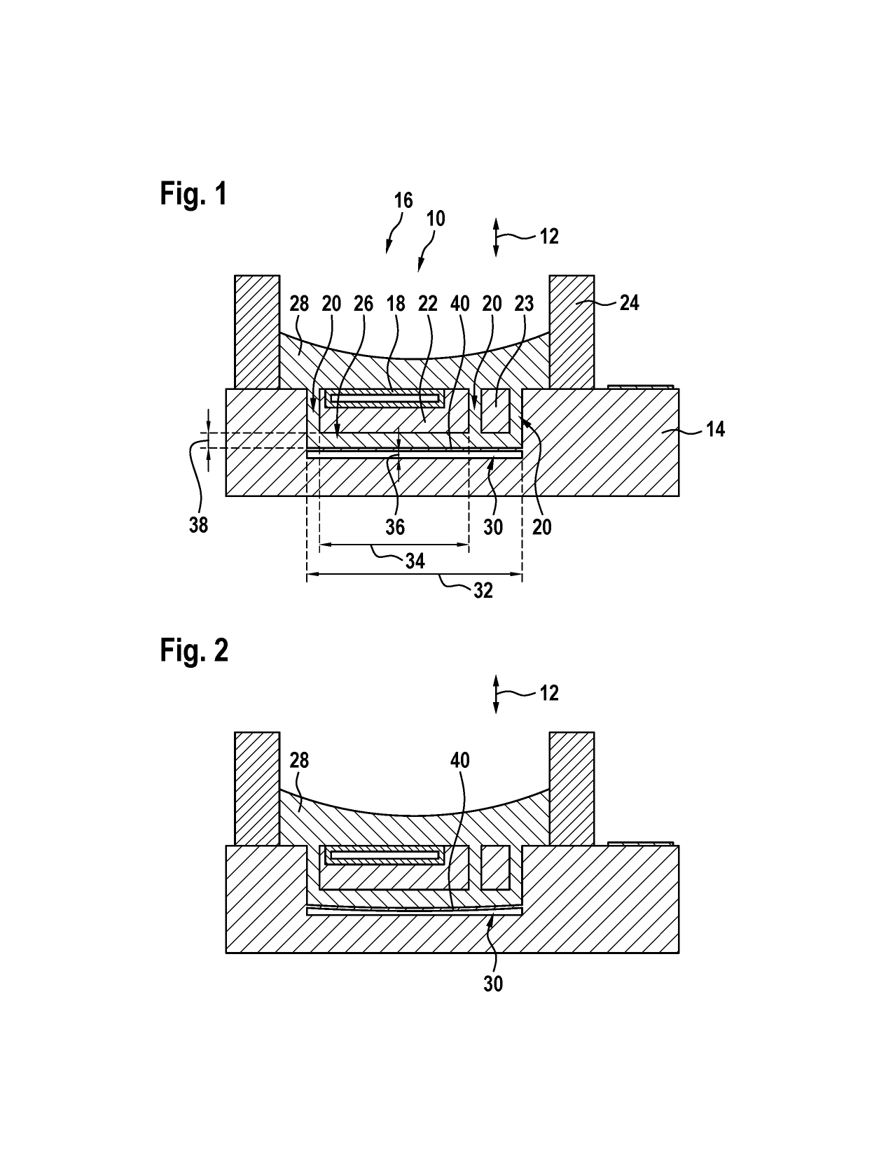

A membrane structure 40 is arranged in the normal direction 12 between the protective mass 28 and the further lower clearance region 30, which membrane structure separates the protective mass 28 from the further lower clearance region 30, but is deflectable to allow the protective mass 28 to expand into the further lower clearance region 30. As a result, material stresses caused by the protective mass 28 can be better decoupled from the sensor element 18, since the protective mass 28 is expandable into the further lower clearance region 30, as shown in FIG. 2, by deflection of the membrane structure 40 in the normal direction 12. For example, this expansion can be ascertained by detecting the deflection of the membrane structure 40, and conclusions regarding a temperature can be drawn according to this.

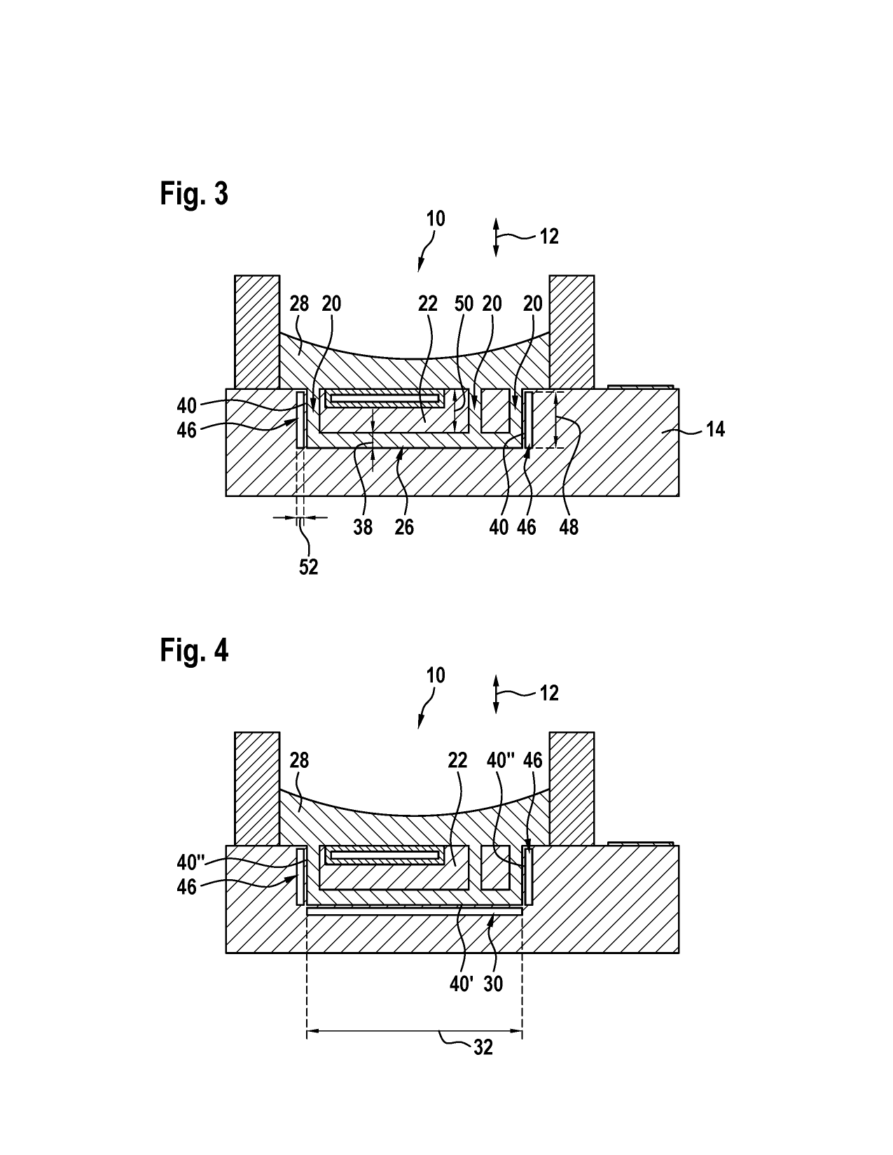

The microsensor 10 in FIG. 3 corresponds to that of FIG. 1; however, instead of the further lower clearance region, a further lateral clearance region 46 that is unfilled by the protective mass 28 and laterally adjoins the lateral clearance region 20 is arranged, which overlaps the carrier element 22 and the lower clearance region 26 in the normal direction 12, in particular completely, and which has a height 48 that is greater than a height 50 of the carrier element 22 and corresponds to a sum of the height 50 of the carrier element 22 and a height 38 of the lower clearance region 26.

The further lateral clearance region 46 extends over a width 52 and in particular also over a length of the carrier element 22 and can extend largely circumferentially around the carrier element 22. The further lateral clearance region 46 adjoins the substrate 14 laterally away from the carrier element 22 and at the bottom in the normal direction 12.

A membrane structure 40 is arranged between the protective mass 28 and the further lateral clearance region 46, which membrane structure separates the protective mass 28 from the further lateral clearance region 46, but is deflectable to allow the protective mass 28 to expand into the further lateral clearance region 46.

The microsensor 10 in FIG. 4 corresponds to that of FIG. 3; however, additionally, as shown in FIG. 1, a further lower clearance region 30 is arranged below the carrier element 22 in the normal direction 12. A width 32 of the further lower clearance region 30 extends laterally as far as the further lateral clearance region 46.

A deflectable membrane structure 40' is arranged between the protective mass 28 and the further lower clearance region 30, and a deflectable membrane structure 40'' is arranged between the protective mass 28 and the further lateral clearance region 46.

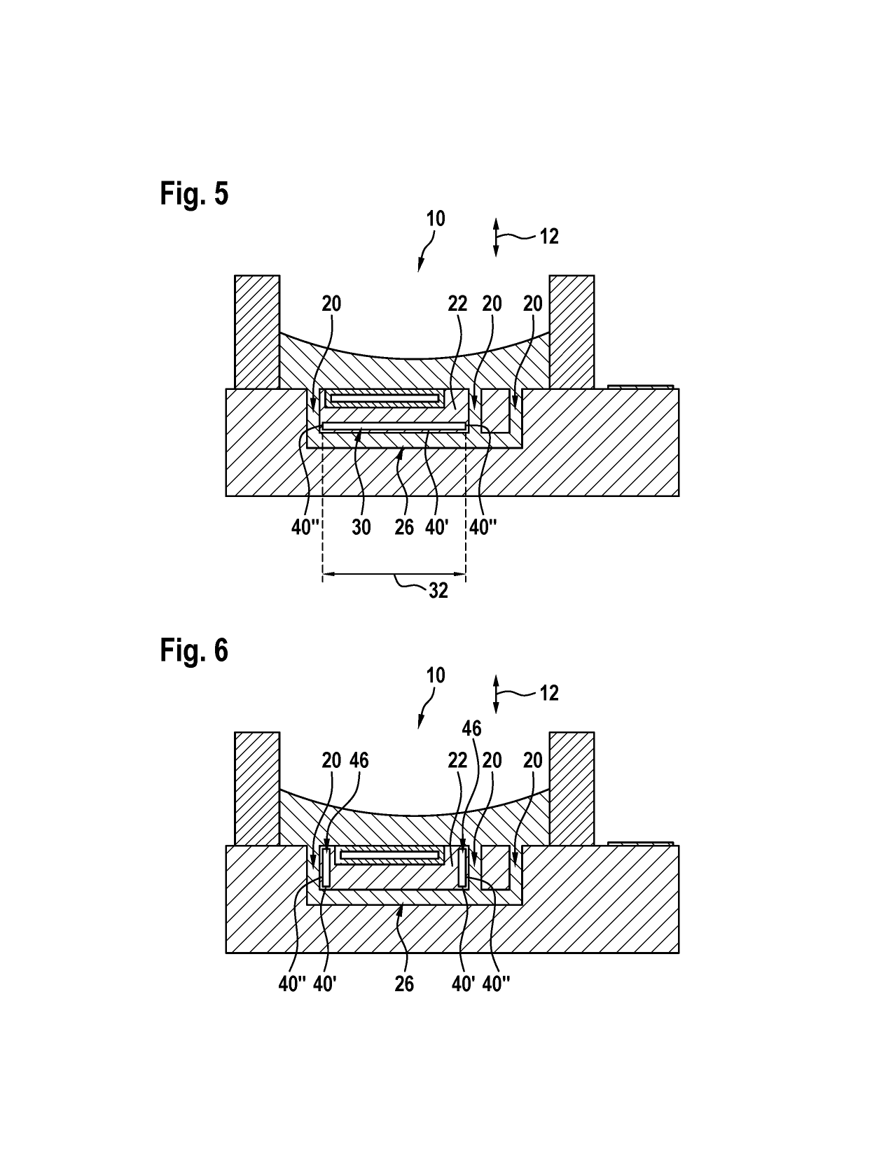

The microsensor 10 in FIG. 5 corresponds to that of FIG. 1; however, the further lower clearance region 30 is arranged as part of the carrier element 22 between the carrier element 22 and the lower clearance region 26 in the normal direction 12. The further lower clearance region 30 is formed in the carrier element 22 and laterally adjoins the lateral clearance region 20. The membrane structure 40 is assigned to the carrier element 22 and comprises a lower membrane structure 40' in the normal direction 12 and a lateral membrane structure 40'', via which the further lower clearance region 30 adjoins the lower clearance region 26 and the lateral clearance region 20. A width of the membrane structure 40' is equal to a width 32 of the further lower clearance region 30. A length of the membrane structure 40' can also be equal to a length of the further lower clearance region 30.

The microsensor 10 in FIG. 6 corresponds to that of FIG. 3; however, the further lateral clearance region 46 is arranged laterally between the carrier element 22 and the lateral clearance region 20 and is formed in the carrier element 22. The membrane structure is assigned to the carrier element 22 and comprises a lower membrane structure 40' in the normal direction 12 and a lateral membrane structure 40'', via which the further lateral clearance region 46 adjoins the lower clearance region 26 and the lateral clearance region 20.

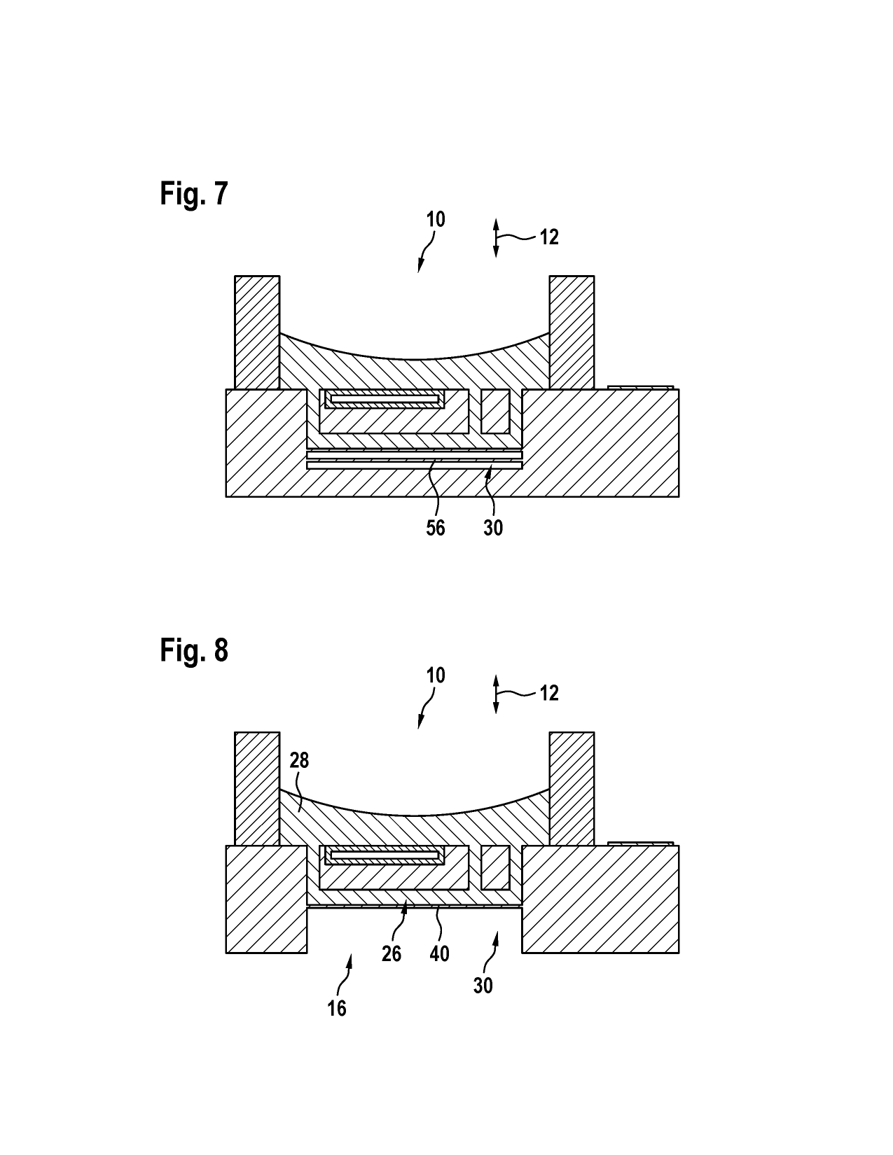

The microsensor 10 in FIG. 7 corresponds to that of FIG. 1; however, the further lower clearance region 30 is subdivided in the normal direction 12 by a further membrane structure 56.

The microsensor 10 in FIG. 8 corresponds to that of FIG. 1; however, the further lower clearance region 30 is open downward in the normal direction 12 toward an environment 16 of the microsensor 10. The membrane structure 40, arranged in the lower clearance region 26 below the protective mass 28 in the normal direction 12, thus directly adjoins the environment 16.

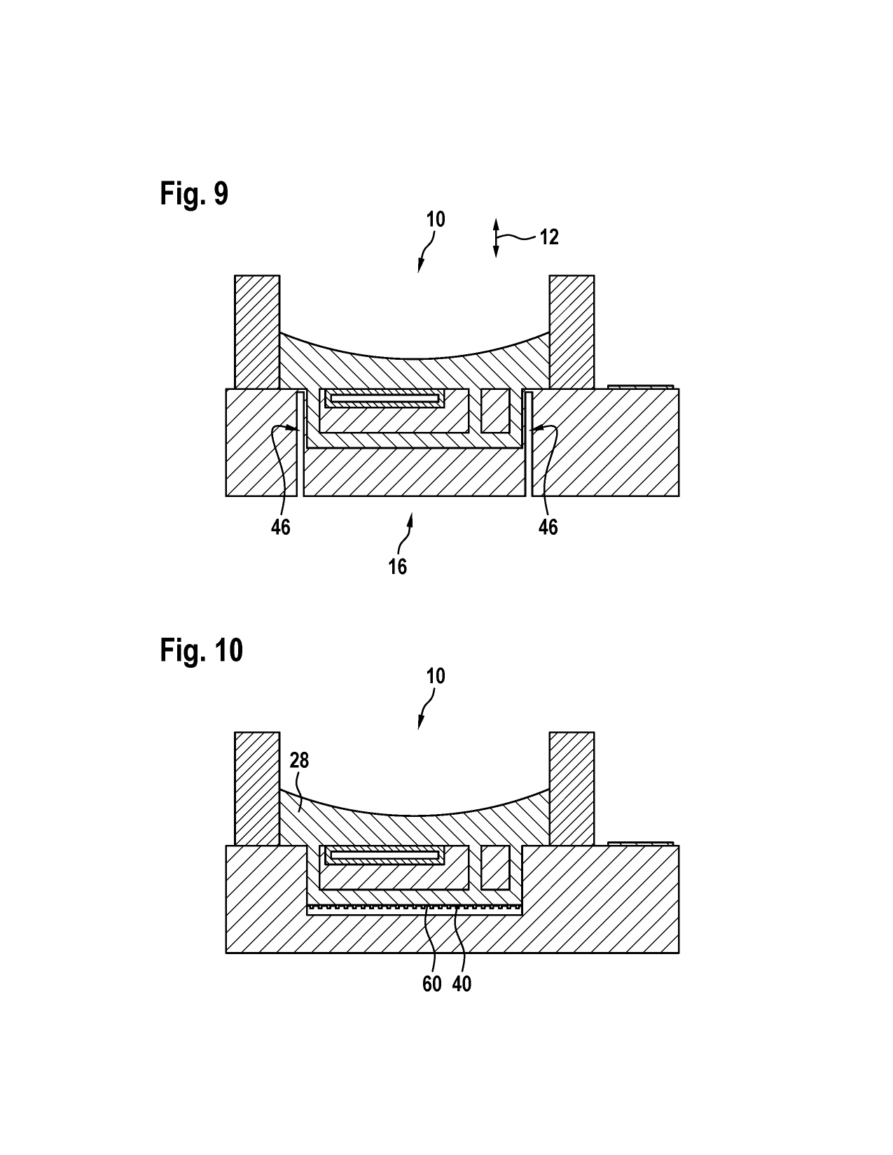

The microsensor 10 in FIG. 9 corresponds to that of FIG. 3; however, the further lateral clearance region 46 is extended downward in the normal direction 12 toward an environment 16 of the microsensor 10 and is open toward the environment 16.

The microsensor 10 in FIG. 10 corresponds to that of FIG. 1; however, the membrane structure 40 comprises openings 60 that are impermeable to the protective mass 28, for example due to the viscosity of the protective mass 28.

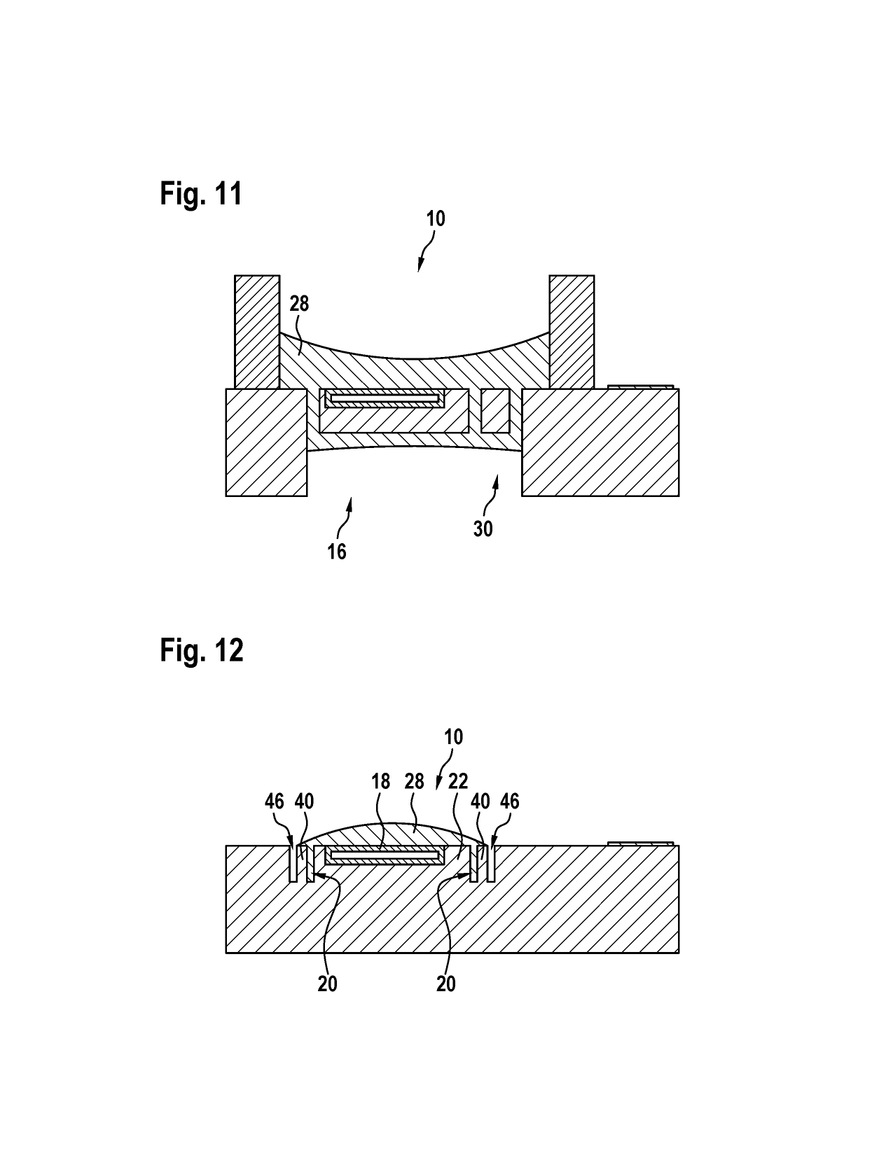

The microsensor 10 in FIG. 11 corresponds to that of FIG. 8; however, the protective mass 28 directly adjoins the further lower clearance region 30, which is completely open toward the environment 16.

A boundary layer, for example a membrane structure as shown in FIG. 8, may have been present on an underside of the protective mass 28 for filling the protective mass 28 and subsequently removed.

The microsensor 10 in FIG. 12 comprises the carrier element 22, which is set free at least largely by the lateral clearance region 20, and a further lateral clearance region 46 is arranged laterally adjoining thereto and delimited therefrom by a membrane structure 40.

The protective mass 28 is introduced above the sensor element 18 and in the lateral clearance region 20. During the filling of the protective mass 28, the lateral clearance region 20 and the membrane structure 40 form a boundary for the spreading of the protective mass 28, and the further lateral clearance region 46 remains unfilled by the protective mass 28.

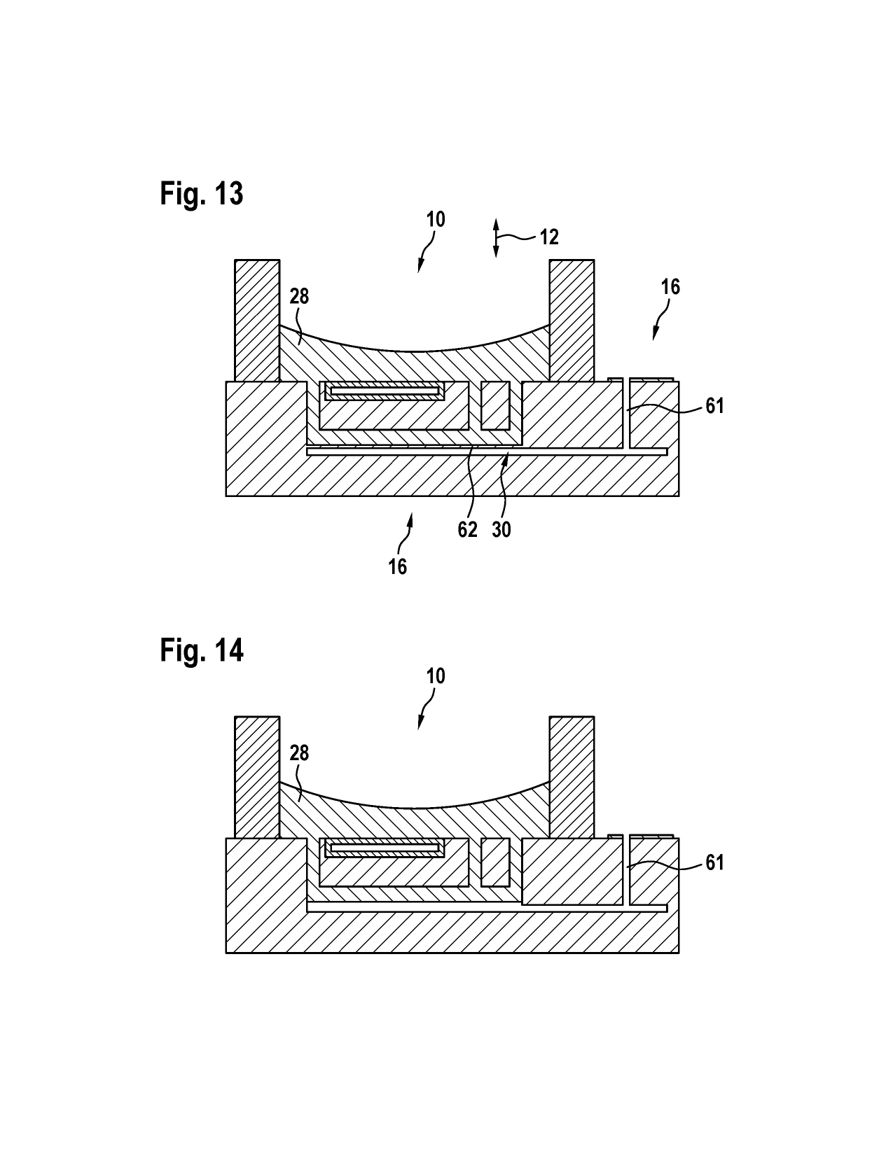

The microsensor 10 in FIG. 13 corresponds to that of FIG. 1; however, the further lower clearance region 30 is not opened downward in the normal direction 12 toward the environment 16, but instead extends further laterally and connects to an access channel 61, which connects the further lower clearance region 30 upward in the normal direction 12 to the environment 16 of the microsensor 10. A boundary layer 62 is arranged between the protective mass 28 and the further lower clearance region 30.

The microsensor 10 in FIG. 14 corresponds to that of FIG. 13; however, the access channel 61 can be used to remove the boundary layer after the protective mass 28 has been poured.

What is claimed:

1. A microsensor for detecting a measured variable, the microsensor comprising:
a substrate constructed from a layer structure in a normal direction;
at least one sensor element configured to detect a measured variable; and
a carrier element that is largely set free from the substrate at least by a lateral clearance region and that includes the sensor element;
wherein, in a normal direction above the sensor element and at least in the lateral clearance region, a gel-like protective mass is situated, which is expandable: (i) into a further lower clearance region that is unfilled by the protective mass and is arranged below the carrier element in the normal direction and/or (ii) into a further lateral clearance region that is situated laterally offset relative to the lateral clearance region.

2. The microsensor according to claim 1, wherein the carrier element is further largely set free in the normal direction below the carrier element by a lower clearance region and the protective mass is also situated in the lower clearance region.

3. The microsensor according to claim 2, wherein the further lower clearance region is arranged in the normal direction below the lower clearance region.

4. The microsensor according to claim 2, wherein the further lower clearance region is arranged in the normal direction between the sensor element and the lower clearance region.

5. The microsensor according to claim 1, wherein the further lateral clearance region is arranged laterally between the lateral clearance region and the substrate.

6. The microsensor according to claim 1, wherein the further lateral clearance region is arranged laterally between the carrier element and the lateral clearance region.

7. The microsensor according to claim 1, wherein the protective mass directly adjoins the further lower clearance region and/or the further lateral clearance region.

8. The microsensor according to claim 1, wherein a membrane structure is arranged between the protective mass and the further lower clearance region and/or the further lateral clearance region, the membrane membrane structure separating the protective mass from the further lower clearance region and/or the further lateral clearance region, and is deflectable to allow the protective mass to expand into the further lower clearance region and/or the further lateral clearance region.

9. The microsensor according to claim 8, wherein the membrane structure is arranged laterally between the protective mass and the further lateral clearance region.

10. The microsensor according to claim 8, wherein the membrane structure is arranged in the normal direction between the protective mass and the further lower clearance region.
